(19) United States
(12) Patent Application Publication
(10) Pub. No.: US 2015/0273653 A1
(43) Pub. Date: Oct. 1, 2015

(54) POLISHING PAD AND METHOD FOR PRODUCING SAME

(71) Applicant: TOYO TIRE & RUBBER CO., LTD., Osaka-shi, Osaka (JP)

(72) Inventor: Yoshiyuki Nakai, Osaka (JP)

(73) Assignee: TOYO TIRE & RUBBER CO., LTD., Osaka-shi, Osaka (JP)

(21) Appl. No.: 14/439,195

(22) PCT Filed: Jun. 25, 2013
(86) PCT No.: PCT/JP2013/067325

§ 371 Date: Apr. 28, 2015

(30) Foreign Application Priority Data
Oct. 31, 2012 (JP) 2012-240425

(51) Int. Cl. B24B 37/24; H01L 21/306

(52) U.S. Cl. CPC B24B 37/24; H01L 21/30625

(57) ABSTRACT

An object of the present invention is to provide a polishing pad capable of maintaining a high level of dimensional stability upon moisture absorption or water absorption though it has high water absorption property and which hardly causes scratches on the surface to be polished of an object to be polished, and a method for producing the same. A polishing pad having a polishing layer comprising a polyurethane foam having fine cells, wherein the polyurethane foam includes a reaction cured body of a polyurethane raw material composition containing (1) an isocyanate-terminated prepolymer (A) obtained by reacting a prepolymer raw material composition (A′) containing an isocyanate monomer, a high molecular weight polyol (a) and a low molecular weight polyol, (2) an isocyanate-terminated prepolymer (B) obtained by reacting a prepolymer raw material composition (B′) containing a polymerized diisocyanate and a high molecular weight polyol (b), and (3) a chain extender; and the polymerized diisocyanate contains pentamers or higher oligomers in an amount of 40% by weight or less.

### TECHNICAL FIELD

The invention relates to a polishing pad capable of performing planarization of materials requiring a high surface planarity such as optical materials including a lens and a reflecting mirror, a silicon wafer, a glass substrate or an aluminum substrates for a hard disc and a product of general metal polishing with stability and a high polishing efficiency. A polishing pad of the invention is preferably employed, especially, in a planarization step of a silicon wafer or a device on which an oxide layer or a metal layer has been formed prior to further stacking an oxide layer or a metal layer thereon.

### BACKGROUND ART

Typical materials requiring surface flatness at high level include a single-crystal silicon disk called a silicon wafer for producing semiconductor integrated circuits (IC, LSI). The surface of the silicon wafer should be flattened highly accurately in a process of producing IC, LSI etc., in order to provide reliable semiconductor connections for various coatings used in manufacturing the circuits. In the step of polishing finish, a polishing pad is generally stuck on a rotatable supporting disk called a platen, while a workpiece such as a semiconductor wafer is stuck on a polishing head. By movement of the two, a relative speed is generated between the platen and the polishing head while polishing slurry having abrasive grains is continuously supplied to the polishing pad, to effect polishing processing.

As polishing characteristics of a polishing pad, it is requested that a polished object is excellent in planarity and in-plane uniformity and a polishing rate is large. A planarity and in-plane uniformity of a polished object can be improved to some extent with a polishing layer higher in elastic modulus. A polishing rate can be bettered by increasing a holding quantity of a slurry on a foam with cells therein.

Polishing pads including a polyurethane foam are proposed as polishing pads that meet the above properties (see Patent Documents 1 and 2). Such a polyurethane foam is produced by a reaction of an isocyanate-terminated prepolymer with a chain extender (curing agent), in which in view of hydrolysis resistance, elastic properties, wear resistance, or the like, a polyether (a polytetramethylene glycol with a number average molecular weight of 500 to 1,600) or a polycarbonate is preferably used as a high molecular polyol component for the isocyanate prepolymer.

However, when the above polishing layer absorbs moisture or water, the cohesion of its hard segment can be reduced so that its dimensional stability can be easily reduced. The polishing pad also has a problem in which in serious cases, it is warped or heaved so that its polishing properties such as planarization properties and in-plane uniformity may gradually change.

Patent Document 3 discloses that in order to improve the retainability slurry, a polymer composition for polishing pads should show a volume swelling rate of 20% or less when it is immersed in water at 23° C. for 72 hours. However, such a polymer composition for polishing pads uses a thermoplastic polymer and thus can hardly form a polishing pad that can maintain a high level of dimensional stability when it absorbs moisture or water.

In order to solve the above problem, a polishing pad capable of maintaining a high level of dimensional stability upon moisture absorption or water absorption though it has high water absorption property, and a method for producing the same have been proposed (Patent Document 4).

According to the mechanical foaming method described in Patent Document 4, it is possible to prepare a polyurethane foam having fine cells having an average cell diameter of 100 μm or less, but air voids each having a diameter of 500 μm or more may occur in the polyurethane foam.

With the miniaturization of semiconductor devices, suppression of the occurrence of scratches (flaws) on a semiconductor wafer surface is required more than ever. Since scratches are caused by air voids in the polyurethane foam, a polyurethane foam free from air voids is demanded.

### PRIOR ART DOCUMENT

### Patent Documents

Patent Document 1: JP-A-2000-17252
Patent Document 2: Japanese patent No. 3359629
Patent Document 3: JP-A-2001-47355
Patent Document 4: JP-A-2008-80478

### SUMMARY OF THE INVENTION

### Problems to be Solved by the Invention

An object of the present invention is to provide a polishing pad capable of maintaining a high level of dimensional stability upon moisture absorption or water absorption though it has high water absorption property and which hardly causes scratches on the surface to be polished of an object to be polished, and a method for producing the same.

### Means for Solving the Problems

As a result of investigations to solve the problems, the inventors have found that the objects can be achieved with the polishing pad described below and the method for producing the same, and have completed the invention.

Specifically, the invention is related to a polishing pad having a polishing layer comprising a polyurethane foam having fine cells, wherein

the polyurethane foam includes a reaction cured body of a polyurethane raw material composition containing:

(1) an isocyanate-terminated prepolymer (A) obtained by reacting a prepolymer raw material composition (A′) containing an isocyanate monomer, a high molecular weight polyol (a) and a low molecular weight polyol,

(2) an isocyanate-terminated prepolymer (B) obtained by reacting a prepolymer raw material composition (B′) containing a polymerized diisocyanate and a high molecular weight polyol (b), and

(3) a chain extender; and

the polymerized diisocyanate contains pentamers or higher oligomers in an amount of 40% by weight or less.

In conventional polishing layers, the cohesion of the hard segment can be easily reduced during absorption of moisture or water. It is considered that this is because conventional polishing layers are made of polyurethane foams whose hard segment is formed only by physical crosslinks, and therefore, such polishing layers can more significantly undergo dimensional change due to elongation, warpage, or the like as they absorb more moisture or water.

As raw materials for the polyurethane foam, (1) the isocyanate-terminated prepolymer (A) obtained by reacting a prepolymer raw material composition (A′) containing an isocyanate monomer, a high molecular weight polyol (a) and a low molecular weight polyol is used in combination with (2) the isocyanate-terminated prepolymer (B) obtained by reacting a prepolymer raw material composition (B′) containing a polymerized diisocyanate and a high molecular weight polyol (b), and these materials are allowed to react with (3) the chain extender, so that chemical crosslinks are regularly introduced into a polymer (regular formation of a three-dimensional crosslinked structure). This makes it possible to increase the cohesion of the hard segment during absorption of moisture or water and to maintain a high level of the dimensional stability of the polishing layer. In addition, a chemically crosslinked network can be expanded by using these two kinds of prepolymers, so that a polyurethane foam having high water absorption property can be obtained. As a result, the holding property of slurry is improved, so that a polishing rate can be increased.

By using a polymerized diisocyanate containing pentamers or higher oligomers in an amount of 40% by weight or less as a raw material for the isocyanate-terminated prepolymer (B), the reactivity between the isocyanate-terminated prepolymer (B) and the chain extender is increased, so that the occurrence of air voids in the polyurethane foam can be suppressed.

Further, in order to enhance the reactivity between the isocyanate-terminated prepolymer (B) and the chain extender, the isocyanate-terminated prepolymer (B) preferably has a viscosity at 50° C. of 8000 mP·s or less.

It is preferable that the high molecular weight polyol (a) is a polyether polyol having a number average molecular weight of 500 to 5000, and the isocyanate monomer includes toluene diisocyanate, dicyclohexylmethane diisocyanate and/or isophorone diisocyanate. It is preferable that the high molecular weight polyol (b) is a polyether polyol having a number average molecular weight of 250 to 1000, the polymerized diisocyanate is a polymerized hexamethylene diisocyanate of isocyanurate type and/or biuret type, and the prepolymer raw material composition (B′) has an NCO index of 3.5 to 6.0. By using these substances, a polyurethane foam can be produced with good handleability, and the effect of the present invention becomes more excellent.

The content of the isocyanate-terminated prepolymer (B) is preferably 5 to 30 parts by weight with respect to 100 parts by weight of the isocyanate-terminated prepolymer (A). If the addition amount of the isocyanate-terminated prepolymer (B) is less than 5 parts by weight, the ratio of chemical crosslinks in the polymer can be insufficient so that the cohesion of the hard segment can be insufficient during absorption of moisture or water and that it may tend to be difficult to maintain the high level dimensional stability of the polishing layer. Further, a polyurethane foam having high water absorption property tends to be difficult to be obtained. On the other hand, if it exceeds 30 parts by weight, the ratio of the chemical crosslinks in the polymer may be so high that the polishing layer may become too hard and brittle, which may reduce the in-plane uniformity of an object to be polished or increase the abrasion loss of the polishing layer, so that the life of the polishing pad may tend to be short.

The number of air voids each having a diameter of 500 μm or more in the polyurethane foam is preferably 5 air voids/φ775 mm or less. The “φ775 mm” means a circle area with a diameter of 775 mm.

The polyurethane foam preferably has an average cell diameter of 20 to 70 μm, a dressing rate of 1.0 μm/minute or less, a dimensional change rate of 0.6% or less when absorbing water, and a bending elastic modulus change rate of 45% or less before and after absorption of water. If the average cell diameter deviates from the above range, the polishing rate may tend to be low, or the planarity (flatness) of an object to be polished after being polished may tend to be low. If the dressing rate is more than 1.0 μm/minute, the life of the polishing pad may be too short, which is not desirable. If the bending elastic modulus change rate when absorbing water exceeds 0.6%, the polishing layer may undergo a significant dimensional change when absorbing moisture or water. If the bending elastic modulus change rate before and after absorption of water exceeds 45%, the polishing characteristics such as edge profile may tend to be deteriorated.

The polyurethane foam preferably has an Asker D hardness of 45 to 65 degrees. If the Asker D hardness is less than 45 degrees, the planarity of an object to be polished may tend to be reduced. On the other hand, if the Asker D hardness is more than 65 degrees, the in-plane uniformity of an object to be polished may tend to be reduced, though the object to be polished will have good planarity. In such a case, the surface of the object to be polished can also be easily scratched.

The invention is also related to a method for producing a polishing pad, comprising the steps of mixing a first component containing an isocyanate-terminated prepolymer with a second component containing a chain extender; and curing the mixture to prepare a polyurethane foam, wherein:

the steps include adding a silicone-based surfactant to the first component containing an isocyanate-terminated prepolymer so that the polyurethane foam contains 0.05 to 10% by weight of the silicone-based surfactant; further stirring the first component together with a non-reactive gas to prepare a cell dispersion liquid in which the non-reactive gas is dispersed in the form of fine cells; and then mixing the second component containing a chain extender with the cell dispersion liquid, followed by curing the mixture to prepare the polyurethane foam, and

the isocyanate-terminated prepolymer is

(1) an isocyanate-terminated prepolymer (A) obtained by reacting a prepolymer raw material composition (A′) containing an isocyanate monomer, a high molecular weight polyol (a) and a low molecular weight polyol, and

(2) an isocyanate-terminated prepolymer (B) obtained by reacting a prepolymer raw material composition (B′) containing a polymerized diisocyanate and a high molecular weight polyol (b), and

the polymerized diisocyanate contains a pentamer or a higher oligomer in an amount of 40% by weight or less.

The production method above can effectively suppress the occurrence of air voids in the polyurethane foam. When the proportion of pentamers or higher oligomers in the polymerized diisocyanate exceeds 40% by weight, the viscosity of the synthesized isocyanate-terminated prepolymer (B) is increased to reduce the reactivity with the chain extender. As a result, the time until curing of the reaction solution becomes longer, during which fine cells made of non-reactive gas are bonded together to be integrated, so that coarse air voids easily occur.

The isocyanate-terminated prepolymer (B) has preferably a viscosity at 50° C. of 8000 mPa·s or less. If the viscosity at 50° C. exceeds 8000 mPa·s, the reactivity between the isocyanate-terminated prepolymer (B) and the chain extender is reduced. As a result, the time until curing of the reaction solution becomes longer, during which fine cells made of non-reactive gas are bonded together to be integrated, so that coarse air voids easily occur.

If the amount of the silicone surfactant is less than 0.05% by weight, it may tend to be difficult to obtain a foam body having fine cells. On the other hand, if it is more than 10% by weight, it may tend to be difficult to obtain a high-hardness polyurethane foam due to the plasticizing effect of the surfactant.

The invention is also related to a method for manufacturing a semiconductor device, including the step of polishing a surface of a semiconductor wafer using the polishing pad.

### Effect of the Invention

The polishing pad of the present invention is capable of maintaining a high level of dimensional stability upon moisture absorption or water absorption though it has high water absorption property, and hardly causes scratches on the surface to be polished of an object to be polished because of containing almost no coarse air voids.

### BRIEF DESCRIPTION OF THE DRAWINGS

FIG. 1 is a schematic diagram showing a typical polishing apparatus for use in CMP polishing.

### MODE FOR CARRYING OUT THE INVENTION

The polishing pad of the invention includes a polishing layer including a polyurethane foam having fine cells. The polishing pad of the invention may be only the polishing layer or a laminated body of the polishing layer and any other layer (such as a cushion layer).

A polyurethane is a preferred material for forming the polishing layer, because polyurethane is excellent in abrasion resistance and polymers with desired physical properties can be easily obtained by varying the raw material composition.

The polyurethane foam includes a reaction cured body of a polyurethane raw material composition containing (1) an isocyanate-terminated prepolymer (A) obtained by reacting a prepolymer raw material composition (A′) containing an isocyanate monomer, a high molecular weight polyol (a) and a low molecular weight polyol, (2) an isocyanate-terminated prepolymer (B) obtained by reacting a prepolymer raw material composition (B′) containing a polymerized diisocyanate and a high molecular weight polyol (b), and (3) a chain extender.

As the isocyanate monomer, a compound known in the field of polyurethane can be used without particular limitation. The isocyanate monomer includes, for example, aromatic diisocyanates such as 2,4-toluene diisocyanate, 2,6-toluene diisocyanate, 2,2′-diphenyl methane diisocyanate, 2,4′-diphenyl methane diisocyanate, 4,4′-diphenyl methane diisocyanate, 1,5-naphthalene diisocyanate, p-phenylene diisocyanate, m-phenylene diisocyanate, p-xylylene diisocyanate and m-xylylene diisocyanate, aliphatic diisocyanates such as ethylene diisocyanate, 2,2,4-trimethyl hexamethylene diisocyanate and 1,6-hexamethylene diisocyanate, and cycloaliphatic diisocyanates such as 1,4-cyclohexane diisocyanate, 4,4′-dicyclohexyl methane diisocyanate, isophorone diisocyanate and norbornane diisocyanate. These may be used alone or as a mixture of two or more thereof. Among the above isocyanate monomers, toluene diisocyanate and dicyclohexylmethane diisocyanate and/or isophorone diisocyanate are preferably used in combination.

On the other hand, the polymerized diisocyanate in the present invention is a mixture of isocyanate-modified bodies formed by polymerization through addition of two or more diisocyanates (e.g., dimers, trimers, pentamers, octamers or dodecamers). For example, the isocyanate-modified body may be of 1) trimethylolpropane adduct type, 2) biuret type, 3) isocyanurate type, or the like. In particular, the isocyanurate type and/or the biuret type are/is preferred.

The polymerized diisocyanate is preferably produced using aliphatic diisocyanate, specifically 1,6-hexamethylene diisocyanate. The polymerized diisocyanate may also be a modification such as a urethane-modified, allophanate-modified, or biuret-modified polymerized diisocyanate.

A polymerized diisocyanate containing pentamers or higher oligomers in an amount of 40% by weight or less is used. It is preferably a polymerized diisocyanate containing pentamers or higher oligomers in an amount of 35% by weight or less, more preferably a polymerized diisocyanate containing pentamers or higher oligomers in an amount of 30% by weight or less, and, in particular, preferably a polymerized diisocyanate containing pentamers or higher oligomers in an amount of 25% by weight or less.

As the high molecular weight polyol (a) and (b), those usually used in the art of polyurethane can be exemplified. Examples thereof include polyether polyols represented by polytetramethylene ether glycol and polyethylene glycol; polyester polyols represented by polybutylene adipate; polyester polycarbonate polyols exemplified by reaction products of polyester glycol such as polycaprolactone polyol or polycaprolactone and alkylene carbonate; polyester polycarbonate polyols obtained by reacting ethylene carbonate with polyvalent alcohol and the reacting the resultant reaction mixture with an organic dicarboxylic acid; and polycarbonate polyols obtained by ester exchange reaction between polyhydroxyl compound and aryl carbonate. These may be used singly or in combination of two or more kinds.

The number average molecular weight of the high molecular weight polyol (a) is not particularly limited, however, from the viewpoint of modulus characteristic of obtainable polyurethane resin it is preferably in the range of 500 to 5000, more preferably in the range of 1000 to 2000. When the number average molecular weight is less than 500, a polyurethane resin obtained therefrom do not have sufficient modulus characteristic, and is likely to be a brittle polymer. And thus, a polishing pad formed of such polyurethane resin is too hard, and result in occurrence of scratch on surface of an object to be polished. Also it is undesired from the viewpoint of life time of polishing pad because ablation is more likely to occur. On the other hand, number average molecular weight exceeding 5000 is not favorable because a polishing pad formed of a polyurethane resin obtainable therefrom is too soft to obtain sufficiently satisfactory planarity.

The number average molecular weight of the high molecular weight polyol (b) is not particularly limited, but is preferably 250 to 1000, and more preferably 250 to 650, from the viewpoint of the dimensional change when the polyurethane resin to be obtained absorbs water and the water absorption rate. If the number average molecular weight is less than 250, the distance between crosslinks is short and the abrasion resistance of the polyurethane resin is reduced, so that the life of the polishing pad may tend to be shortened. On the other hand, if the number average molecular weight is more than 1000, the distance between crosslinks is long, so that water absorption property may be high and dimensional change when absorbing water may tend to be increased.

The low molecular weight polyol is an essential raw material for the isocyanate-terminated prepolymer (A). Examples of the low molecular weight polyol include ethylene glycol, 1,2-propylene glycol, 1,3-propylene glycol, 1,2-butanediol, 1,3-butanediol, 1,4-butanediol, 2,3-butanediol, 1,6-hexanediol, neopentyl glycol, 1,4-cyclohexanedimethanol, 3-methyl-1,5-pentanediol, diethylene glycol, triethylene glycol, 1,4-bis(2-hydroxyethoxy)benzene, trimethylolpropane, glycerin, 1,2,6-hexanetriol, pentaerythritol, tetramethylolcyclohexane, methylglucoside, sorbitol, mannitol, dulcitol, sucrose, 2,2,6,6-tetrakis(hydroxymethyl)cyclohexanol, diethanolamine, N-methyldiethanolamine, and triethanolamine. One or more of these polyols may be used alone or in any combination. In addition, the low molecular weight polyol may also be used as a raw material for the isocyanate-terminated prepolymer (B) if necessary.

A low molecular weight polyamine such as ethylenediamine, tolylenediamine, diphenylmethanediamine, or diethylenetriamine may also be used as a raw material for the isocyanate-terminated prepolymer (A) and (B) concomitantly. An alcoholamine such as monoethanolamine, 2-(2-aminoethylamino)ethanol, or monopropanolamine may also be used concomitantly. These materials may be used alone or two or more of these may be used concomitantly.

The amount of the low molecular weight polyol, the low molecular weight polyamine, or the like is, although not limited particularly, preferably from 10 to 25% by mole, based on the amount of all the active hydrogen group-containing compounds used as raw materials for the isocyanate-terminated prepolymer (A), while it may be appropriately determined depending on the desired properties of the polishing pad (polishing layer) to be produced.

It is preferably an isocyanate-terminated prepolymer (B) having a viscosity at 50° C. of 8000 mPa·s or less, more preferably an isocyanate-terminated prepolymer (B) having a viscosity at 50° C. of 7000 mPa·s or less, and, in particular, preferably an isocyanate-terminated prepolymer (B) having a viscosity at 50° C. of 5000 mPa·s or less. The viscosity of the isocyanate-terminated prepolymer (B) may be adjusted mainly by the mixing ratio of the isocyanate-modified body in the polymerized diisocyanate as a raw material.

When the isocyanate-terminated prepolymer (B) is prepared, the polymerized diisocyanate and the high molecular weight polyol (b) are preferably mixed in such a manner that the NCO index falls within the range of 3.5 to 6.0, more preferably within the range of 3.5 to 4.5.

In a case where a polyurethane foam is produced by means of a prepolymer method, a chain extender is used in curing of a prepolymer. A chain extender is an organic compound having at least two active hydrogen groups and examples of the active hydrogen group include: a hydroxyl group, a primary or secondary amino group, a thiol group (SH) and the like. Concrete examples of the chain extender include: polyamines such as 4,4′-methylenebis(o-chloroaniline)(MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 4,4′-diamino-3,3′,5,5′-tetraethyldiphenylmethane, 4,4′-diamino-3,3′-diisopropyl-5.5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5.5′-dimethyldiphenylmethane, N,N′-di-sec-butyl-4,4′-diaminophenylmethane, 3,3′-diethyl-4,4′-diaminodiphenylmethane, m-xylylenediamine, N,N′-di-sec-butyl-p-phenylenediamine, m-phenylenediamine and p-xylylenediamine; low-molecular-weight polyol component; and a low-molecular-weight polyamine component. The chain extenders described above may be used either alone or in mixture of two kinds or more.

The mixing ratio of the isocyanate-terminated prepolymer (A), the isocyanate-terminated prepolymer (B), and the chain extender may be varied depending on the molecular weight of each material and the desired physical properties of the polishing pad. The amount of addition of the isocyanate-terminated prepolymer (B) is preferably from 5 to 30 parts by weight, more preferably from 5 to 20 parts by weight, based on 100 parts by weight of the isocyanate-terminated prepolymer (A). Further, in order to obtain a polishing pad having desired polishing properties, the number of isocyanate groups in the prepolymers is preferably from 0.8 to 1.2, more preferably from 0.99 to 1.15 per the number of active hydrogen groups (hydroxyl groups and/or amino groups) in the chain extender. If the number of isocyanate groups is outside the range, insufficient curing could occur so that the required specific gravity or hardness could not be achieved, which tends to decrease the polishing properties.

The polyurethane foam is preferably produced by melting method in view of cost, working environment and so on, while it may be produced by application of any known urethane foaming techniques such as melting method and solution technique.

According to the invention, the polyurethane foam production is performed using a prepolymer process. Polyurethane resin produced by prepolymer process has a preferably excellent physical properties.

Note that an isocyanate-terminated prepolymer (A) and (B) with a molecular weight of the order in the range of from 800 to 5000 is preferable because of excellency in workability and physical properties.

Specifically, a first component containing the isocyanate-terminated prepolymer (A) and the isocyanate-terminated prepolymer (B) is mixed with a second component containing a chain extender, followed by curing, to produce the polyurethane foam.

The method for producing the polyurethane foam may be a method of adding hollow beads, a mechanical foaming method (including mechanical frothing), a chemical foaming method, or the like. While any combination of these methods may be used, in particular, a mechanical foaming method is preferably performed using a silicone surfactant including a copolymer of polyalkylsiloxane and polyether. Examples of compounds suitable as the silicone surfactant include SH-192 and L-5340 (manufactured by Dow Corning Toray Silicone Co., Ltd.), B8443 and B8465 (manufactured by Goldschmidt Chemical Corporation), and the like. The silicone surfactant is preferably added to the polyurethane raw material composition in an amount of 0.05 to 10% by weight, and more preferably 0.1 to 5% by weight.

Various additives may be mixed; such as a stabilizer including an antioxidant, a lubricant, a pigment, a filler, an antistatic agent and others.

Description will be given of an example of a method of producing a polyurethane foam having fine cells constituting a polishing pad (a polishing layer) below. A method of manufacturing such a polyurethane foam has the following steps:

### 1) Foaming Step of Preparing Cell Dispersion Liquid

The step includes adding a silicone surfactant to the first component containing the isocyanate-terminated prepolymers (A) and (B) so that the polyurethane foam will contain 0.05 to 10% by weight of the silicone surfactant and stirring the mixture in the presence of a non-reactive gas to form a cell dispersion liquid in which the non-reactive gas is dispersed in the form of fine cells. In a case where the prepolymer is solid at an ordinary temperature, the prepolymer is preheated to a proper temperature and used in a molten state.

### 2) Curing Agent (Chain Extender) Mixing Step

The second component containing a chain extender is added into the cell dispersion liquid, which is agitated to thereby obtain a foaming reaction liquid.

### 3) Casting Step

The forming reaction liquid is cast into a mold.

### 4) Curing Step

The foaming reaction liquid having been cast into the mold is heated and reaction-cured.

The non-reactive gas used for forming fine cells is preferably not combustible, and is specifically nitrogen, oxygen, a carbon dioxide gas, a rare gas such as helium and argon, and a mixed gas thereof, and the air dried to remove water is most preferable in respect of cost.

As a stirrer for dispersing the silicone surfactant-containing first component to form fine cells with the non-reactive gas, known stirrers can be used without particular limitation, and examples thereof include a homogenizer, a dissolver, a twin-screw planetary mixer etc. The shape of a stirring blade of the stirrer is not particularly limited either, but a whipper-type stirring blade is preferably used to form fine cells.

In a preferable mode, different stirrers are used in stirring for forming a cell dispersion liquid in the stirring step and in stirring for mixing an added chain extender in the mixing step, respectively. In particular, stirring in the mixing step may not be stirring for forming cells, and a stirrer not generating large cells is preferably used. Such a stirrer is preferably a planetary mixer. The same stirrer may be used in the stirring step and the mixing step, and stirring conditions such as revolution rate of the stirring blade are preferably regulated as necessary.

In the method of producing the polyurethane foam with fine cells, heating and post-curing of the foam obtained after casting and reacting the forming reaction liquid in a mold until the dispersion lost fluidity are effective in improving the physical properties of the foam, and are extremely preferable. The forming reaction liquid may be cast in a mold and immediately post-cured in a heating oven, and even under such conditions, heat is not immediately conducted to the reactive components, and thus the diameters of cells are not increased. The curing reaction is conducted preferably at normal pressures to stabilize the shape of cells.

In the production of the polyurethane foam, a known catalyst promoting polyurethane reaction, such as tertiary amine-based catalysts, may be used. The type and amount of the catalyst added are determined in consideration of flow time in casting in a predetermined mold after the mixing step.

Production of the polyurethane foam may be in a batch system where each component is weighed out, introduced into a vessel and mixed or in a continuous production system where each component and a non-reactive gas are continuously supplied to, and stirred in, a stirring apparatus and the resulting forming reaction liquid is transferred to produce molded articles.

A manufacturing method of a polishing pad may be performed in ways: in one of which a prepolymer which is a raw material from which a polishing pad (a polishing layer) is made is put into a reaction vessel, thereafter a chain extender is mixed into the prepolymer, the mixture is agitated, thereafter the mixture is cast into a mold with a predetermined size to thereby prepare a block and the block is sliced with a slicer like a planer or a band saw; and in another of which in the step of casting into the mold, a thin sheet may be directly produced. Besides, a still another way may be adopted in which a resin of raw material is melted, the melt is extruded through a T die to thereby mold a polyurethane foam directly in the shape of a sheet.

The number of air voids each having a diameter of 500 μm or more in the polyurethane foam is preferably 5 air voids/φ775 mm or less, and more preferably 3 air voids/φ775 mm or less.

The average cell diameter of the polyurethane foam is preferably from 20 to 70 μm, more preferably from 30 to 60 μm.

The polyurethane foam preferably has a dressing rate of 1.0 μm/minute or less, and more preferably 0.8 μm/minute or less.

The polyurethane foam preferably has a dimensional change rate of 0.6% or less, and more preferably 0.4% or less, when absorbing water.

The polyurethane foam preferably has a bending elastic modulus change rate of 45% or less before and after absorption of water, and more preferably 40% or less.

A hardness of the polyurethane foam is preferably in the range of from 45 to 65 degrees, more preferably in the range of from 50 to 60 degrees as measured with an Asker D hardness meter.

A polishing pad (polishing layer) of the invention is preferably provided with a depression and a protrusion structure for holding and renewing a slurry. Though in a case where the polishing layer is formed with a fine foam, many openings are on a polishing surface thereof which works so as to hold the slurry, a depression and protrusion structure are preferably provided on the surface of the polishing side thereof in order to achieve more of holdability and renewal of the slurry or in order to prevent induction of dechuck error, breakage of a wafer or decrease in polishing efficiency. The shape of the depression and protrusion structure is not particularly limited insofar as slurry can be retained and renewed, and examples include latticed grooves, concentric circle-shaped grooves, through-holes, non-through-holes, polygonal prism, cylinder, spiral grooves, eccentric grooves, radial grooves, and a combination of these grooves. The groove pitch, groove width, groove thickness etc. are not particularly limited either, and are suitably determined to form grooves. These depression and protrusion structure are generally those having regularity, but the groove pitch, groove width, groove depth etc. can also be changed at each certain region to make retention and renewal of slurry desirable.

The method of forming the depression and protrusion structure is not particularly limited, and for example, formation by mechanical cutting with a jig such as a bite of predetermined size, formation by casting and curing resin in a mold having a specific surface shape, formation by pressing resin with a pressing plate having a specific surface shape, formation by photolithography, formation by a printing means, and formation by a laser light using a CO₂ gas laser or the like.

No specific limitation is placed on a thickness of a polishing layer, but a thickness thereof is about 0.8 to 4 mm, preferably 1.5 to 2.5 mm.

A polishing pad of the invention may also be a laminate of a polishing layer and a cushion sheet adhered to each other.

The cushion sheet (cushion layer) compensates for characteristics of the polishing layer. The cushion layer is required for satisfying both planarity and uniformity which are in a tradeoff relationship in CMP. Planarity refers to flatness of a pattern region upon polishing an object of polishing having fine unevenness generated upon pattern formation, and uniformity refers to the uniformity of the whole of an object of polishing. Planarity is improved by the characteristics of the polishing layer, while uniformity is improved by the characteristics of the cushion layer. The cushion layer used in the polishing pad of the present invention is preferably softer than the polishing layer.

The material forming the cushion layer is not particularly limited, and examples of such material include a nonwoven fabric such as a polyester nonwoven fabric, a nylon nonwoven fabric or an acrylic nonwoven fabric, a nonwoven fabric impregnated with resin such as a polyester nonwoven fabric impregnated with polyurethane, polymer resin foam such as polyurethane foam and polyethylene foam, rubber resin such as butadiene rubber and isoprene rubber, and photosensitive resin.

Means for adhering the polishing layer to the cushion layer include: for example, a method in which a double-sided tape is sandwiched between the polishing layer and the cushion layer, followed by pressing.

The double-sided tape is of a common construction in which adhesive layers are provided on both surfaces of a substrate such as a nonwoven fabric or a film. It is preferable to use a film as a substrate with consideration given to prevention of permeation of a slurry into a cushion sheet. A composition of an adhesive layer is, for example, of a rubber-based adhesive, an acrylic-based adhesive or the like. An acrylic-based adhesive is preferable because of less of a content of metal ions, to which consideration is given. Since a polishing layer and a cushion sheet is sometimes different in composition from each other, different compositions are adopted in respective adhesive layers of double-sided tape to thereby also enable adhesive forces of the respective adhesive layers to be adjusted to proper values.

A polishing pad of the invention may be provided with a double-sided tape on the surface of the pad adhered to a platen. As the double-sided tape, a tape of a common construction can be used in which adhesive layers are, as described above, provided on both surfaces of a substrate. As the substrate, for example, a nonwoven fabric or a film is used. Preferably used is a film as a substrate since separation from the platen is necessary after the use of a polishing pad. As a composition of an adhesive layer, for example, a rubber-based adhesive or an acrylic-based adhesive is exemplified. Preferable is an acrylic-based adhesive because of less of metal ions in content to which consideration is given.

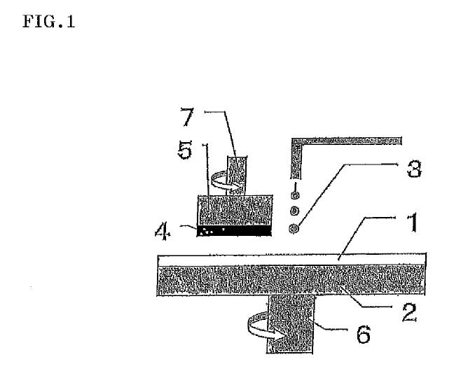

A semiconductor device is fabricated after operation in a step of polishing a surface of a semiconductor wafer with a polishing pad. The term, a semiconductor wafer, generally means a silicon wafer on which a wiring metal and an oxide layer are stacked. No specific limitation is imposed on a polishing method of a semiconductor wafer or a polishing apparatus, and polishing is performed with a polishing apparatus equipped, as shown in FIG. 1, with a polishing platen 2 supporting a polishing pad (a polishing layer) 1, a polishing head 5 holding a semiconductor wafer 4, a backing material for applying a uniform pressure against the wafer and a supply mechanism of a polishing agent 3. The polishing pad 1 is mounted on the polishing platen 2 by adhering the pad to the platen with a double-sided tape. The polishing platen 2 and the polishing head 5 are disposed so that the polishing pad 1 and the semiconductor wafer 4 supported or held by them oppositely face each other and provided with respective rotary shafts 6 and 7. A pressure mechanism for pressing the semiconductor wafer 4 to the polishing pad 1 is installed on the polishing head 5 side. During polishing, the semiconductor wafer 4 is polished by being pressed against the polishing pad 1 while the polishing platen 2 and the polishing head 5 are rotated and a slurry is fed. No specific limitation is placed on a flow rate of the slurry, a polishing load, a polishing platen rotation number and a wafer rotation number, which are properly adjusted.

Protrusions on the surface of the semiconductor wafer 4 are thereby removed and polished flatly. Thereafter, a semiconductor device is produced therefrom through dicing, bonding, packaging etc. The semiconductor device is used in an arithmetic processor, a memory etc.

### EXAMPLES

Description will be given of the invention with examples, while the invention is not limited to description in the examples.

### [Measurement and Evaluation Method]

### (Measurement of Number-Average Molecular Weight)

A number-average molecular weight was measured by GPC (a Gel Permeation Chromatography) and a value as measured was converted in terms of standard polystylene molecular weight, and the apparatus and conditions in operation were as follows:

GPC apparatus was an apparatus manufactured by Shimadzu Corp., with Model Number of LC-10A.

Columns that were used in measurement were ones manufactured by Polymer Laboratories Co., in which three columns were in connection including (PL gel, 5 μm and 500 Å), (PL gel, 5 μm and 100 Å) and (PL gel, 5 μm and 50 Å).

A flow rate was 1.0 ml/min.

A concentration was 1.0 g/l.

An injection quantity was 40 μl.

A column temperature was 40° C.

An eluent was tetrahydrofuran.

### (Measurement of Viscosity)

After heating the synthesized isocyanate-terminated prepolymer (B) to 50° C. in an oven, the viscosity of the prepolymer (B) was measured using an H-type viscometer (TV-10, manufactured by Toki Sangyo Co., Ltd.) under the condition of rotor H4×20 rpm.

### (Measurement of Average Cell Diameter)

The prepared polyurethane foam was sliced with a microtome cutter into measurement samples each with the thinnest possible thickness of 1 mm or less. A surface of a sample was photographed with a scanning electron microscope (S-3500N, Hitachi Science Systems Co., Ltd.) at a magnification of ×100. An effective circular diameter of each of all cells in an arbitrary area was measured with an image analyzing soft (manufactured by MITANI Corp. with a trade name WIN-ROOF) and an average cell diameter was calculated from the measured values.

### (Measurement of Number of Air Voids)

The prepared polyurethane foam block (900×1000×40 mm) was sliced and the surface of the sliced piece was buffed to obtain a polyurethane foam sheet with 2 mm in thickness. The polyurethane foam sheet was placed on a light projection platform that had been scribed with a circle of φ30.5 inches (φ775 mm), and then the number of air voids each having a diameter of 500 μm or more within the region of φ30.5 inches was counted using a 7-times graduated magnifying glass.

### (Measurement of Specific Gravity)

Determined according to JIS Z8807-1976. A manufactured polyurethane foam cut out in the form of a strip of 4 cm×8.5 cm (thickness: arbitrary) was used as a sample for measurement of specific gravity and left for 16 hours in an environment of a temperature of 23±2° C. and a humidity of 50%±5%. Measurement was conducted by using a specific gravity hydrometer (manufactured by Sartorius Co., Ltd).

### (Measurement of Hardness)

Measurement is conducted according to JIS K6253-1997. A manufactured polyurethane foam cut out in a size of 2 cm×2 cm (thickness: arbitrary) was used as a sample for measurement of hardness and left for 16 hours in an environment of a temperature of 23±2° C. and a humidity of 50%±5%. At the time of measurement, samples were stuck on one another to a thickness of 6 mm or more. A hardness meter (Asker D hardness meter, manufactured by Kobunshi Keiki Co., Ltd.) was used to measure hardness.

### (Measurement of Dimensional Change Rate Upon Absorption of Water)

The measurement was performed according to JIS K 7312. The resulting polyurethane foam was cut into a sample 20 mm in width, 50 mm in length, and 1.27 mm in thickness. The sample was immersed in distilled water at 25° C. for 48 hours, and the dimensional change rate was calculated by substituting its lengths before and after the immersion into the following formula: dimensional change rate (%)=[(the length after the immersion−the length before the immersion)/(the length before the immersion)]×100.

(Measurement of Bending Elastic Modulus Change Rate Before and after Water Absorption)

A sample (1.0 mm in width, 3.0 mm in length, and 2.0 mm in thickness) was cut out from the prepared polyurethane foam. The bending elastic modulus of the sample before water absorption was measured using a measuring apparatus (Desktop Testing System 5864, manufactured by Instron Corporation) under the following conditions: 22 mm in distance between fulcrums of a bending strength measuring jig, 0.6 mm/minute of crosshead speed, and 6.0 mm of displacement amount. The bending elastic modulus was calculated from the following equation.

Bending elastic modulus=Stress difference between two points on straight line part/Strain difference between two points on the same straight line part

In addition, the sample was immersed in distilled water at 25° C. for 48 hours to absorb water, and then the bending elastic modulus of the sample after water absorption was measured by the same method as described above.

The bending elastic modulus change rate was calculated from the following equation.

Bending elastic modulus change rate=[(Bending elastic modulus before water absorption−Bending elastic modulus after water absorption)/Bending elastic modulus before water absorption]×100

### (Measurement of Dressing Rate)

The prepared polyurethane foam sheet (380 mm, 1.25 mm in thickness) was bonded to a platen with a double-faced tape and dressed under the following conditions.

A dressing apparatus: MAT-BC15, manufactured by MAT Inc.

A dresser: SAESOL C7

A forced drive rotation speed: 115 rpm

A platen rotation speed: 70 rpm

A dressing load: 9.7 pounds

A water absorption rate: 200 ml/minute

A dressing time: 1 hours

After completion of the dressing, the polyurethane foam sheet was cut into a strip sample with 10 mm in width and 380 mm in length, and the double-faced tape on the back side was peeled off to obtain a sample. The thickness of the sample was measured at points (18 points in total) spaced at intervals of 20 mm horizontally from the central point to obtain a difference (μm) in abrasion loss between the undressed central point and the each measurement point. The dressing rate was calculated from the following equation.

Dressing rate (μm/minute)=Average difference in abrasion loss at 18 points/60

### Example 1

To a vessel were added 1,229 parts by weight of toluene diisocyanate (a mixture of toluene 2,4-diisocyanate/toluene 2,6-diisocyanate=80/20), 272 parts by weight of 4,4′-dicyclohexylmethane diisocyanate, 1,901 parts by weight of polytetramethylene ether glycol with a number average molecular weight of 1,018, and 198 parts by weight of diethylene glycol. The mixture was allowed to react at 70° C. for 4 hours to give an isocyanate-terminated prepolymer (A).

Also, to a vessel were added 100 parts by weight of a polymerized 1,6-hexamethylene diisocyanate (DURANATE TLA-100 (isocyanurate type) manufactured by Asahi Kasei Chemicals Corporation; dimer: 15% by weight, trimer: 62% by weight, pentamer: 4% by weight, octamer: 19% by weight) and 17.3 parts by weight of polytetramethylene ether glycol having a number average molecular weight of 250 (NCO index: 4), and the mixture was allowed to react at 100° C. for 3 hours to obtain an isocyanate-terminated prepolymer (B1) (viscosity at 50° C.: 2500 mPa·s, NCO weight percentage: 15.0% by weight).

To a polymerization vessel were added 100 parts by weight of the prepolymer (A), 16 parts by weight of the prepolymer (B1), and 3 parts by weight of a silicone surfactant (B8465 manufactured by Goldschmidt Chemical Corporation), and mixed. The mixture was adjusted to 70° C. and reduced in pressure and degassed. The mixture was then vigorously stirred with a stirring blade at a rotation number of 900 rpm for about 4 minutes in such a manner that bubbles were incorporated into the reaction system. To the mixture was added 33.5 parts by weight (NCO index: 1.1) of 4,4′-methylenebis(o-chloroaniline) (MOCA) which had been previously melted at 120° C. The mixture liquid was stirred for about 70 seconds and then poured into a loaf-shaped open mold (casting vessel). When the mixture liquid lost its fluidity, it was placed in an oven and subjected to post curing at 100° C. for 16 hours so that a polyurethane foam block was obtained.

While heated at about 80° C., the polyurethane foam block was sliced using a slicer (VGW-125 manufactured by AMITEC Corporation) so that a polyurethane foam sheet was obtained. The surface of the sheet was then buffed with a buffing machine (manufactured by AMITEC Corporation) until the sheet had a thickness of 1.27 mm. As a result, the sheet had adjusted thickness accuracy. The buffed sheet was formed by punching to have a diameter of 61 cm, and concentric grooves, 0.25 mm in width, 1.50 mm in pitch, and 0.40 mm in depth, were formed in the surface of the sheet using a grooving machine (manufactured by Techno Corporation) so that a polishing layer was obtained. A double-sided tape (Double Tack Tape manufactured by Sekisui Chemical Co., Ltd.) was bonded to the surface of the polishing layer opposite to the grooved surface using a laminator. The surface of a corona-treated cushion sheet (Toraypef manufactured by Toray Industries, Inc. (0.8 μm-thick polyethylene foam)) was buffed. The buffed cushion sheet was bonded to the double-sided tape using a laminator. Another double-sided tape was also bonded to the other side of the cushion sheet using a laminator so that a polishing pad was prepared.

### Example 2

To a vessel were added 100 parts by weight of a polymerized 1,6-hexamethylene diisocyanate (DURANATE TPA-100 (isocyanurate type) manufactured by Asahi Kasei Chemicals Corporation; dimer: 2% by weight, trimer: 66% by weight, pentamer: 19% by weight, octamer: 18% by weight) and 17.2 parts by weight of polytetramethylene ether glycol having a number average molecular weight of 250 (NCO index: 4), and the mixture was allowed to react at 100° C. for 3 hours to obtain an isocyanate-terminated prepolymer (B2) (viscosity at 50° C.: 7000 mPa·s, NCO weight percentage: 14.8% by weight).

A polishing pad was prepared in the same manner as in Example 1, except that in Example 1, the prepolymer (B2) (16 parts by weight) was used in place of the prepolymer (B1) (16 parts by weight) and the addition amount of MOCA was changed to 33.4 parts by weight from 33.5 parts by weight.

### Example 3

A polishing pad was prepared in the same manner as in Example 1, except that in Example 1, the addition amount of the prepolymer (B1) was changed to 8 parts by weight from 16 parts by weight and the addition amount of MOCA was changed to 30.0 parts by weight from 33.5 parts by weight.

### Comparative Example 1

To a vessel were added 100 parts by weight of a polymerized 1,6-hexamethylenediisocyanate (Sumijule N-3300 (isocyanurate type) manufactured by Sumika Bayer Urethane Co., Ltd.; trimer: 55% by weight, pentamer: 22% by weight, octamer: 11% by weight, dodecamer 12% by weight) and 16.3 parts by weight of polytetramethylene ether glycol having a number average molecular weight of 250 (NCO index: 4), and the mixture was allowed to react at 100° C. for 3 hours to obtain an isocyanate-terminated prepolymer (B3) (viscosity at 50° C.: 11500 mPa·s, NCO weight percentage: 14.2% by weight).

A polishing pad was prepared in the same manner as in Example 1, except that in Example 1, the prepolymer (B3) (16 parts by weight) was used in place of the prepolymer (B1) (16 parts by weight) and the addition amount of MOCA was changed to 33.1 parts by weight from 33.5 parts by weight.

TABLE 1

| | | | | | Comparative |
|---|---|---|---|---|---|
| | | Example 1 | Example 2 | Example 3 | example 1 |
| Prepolymer (A) (parts by weight) | | 100 | 100 | 100 | 100 |
| Prepolymer (B1) (parts by weight) | | 16 | — | 8 | — |
| Prepolymer (B2) (parts by weight) | | — | 16 | — | — |
| Prepolymer (B3) (parts by weight) | | — | — | — | 16 |
| MOCA (parts by weight) | | 33.5 | 33.4 | 30.0 | 33.1 |
| B8456 (parts by weight) | | 3 | 3 | 3 | 3 |
| Physical | Average cell diameter (μm) | 43 | 44 | 42 | 45 |
| properties | Number of air voids (per φ775 mm) | 1 | 0 | 1 | 6 |
| | Specific gravity | 0.75 | 0.75 | 0.75 | 0.75 |
| | D hardness (degree) | 54 | 54 | 53 | 54 |
| | Dimensional change rate (%) | 0.35 | 0.35 | 0.40 | 0.34 |
| | Bending elastic modulus change | 33.0 | 34.0 | 38.0 | 33.5 |
| | rate (%) | | | | |
| | Dressing rate (μm/minute) | 0.65 | 0.65 | 0.43 | 0.66 |

### INDUSTRIAL APPLICABILITY

A polishing pad of the invention is capable of performing planarization materials requiring a high surface planarity such as optical materials including a lens and a reflective mirror, a silicon wafer, an aluminum substrate and a product of general metal polishing with stability and a high polishing efficiency. A polishing pad of the invention is preferably employed, especially, in a planarization step of a silicon wafer or a device on which an oxide layer or a metal layer has been formed prior to further stacking an oxide layer or a metal layer thereon.

### DESCRIPTION OF REFERENCE SIGNS

In the drawings, reference numeral 1 represents a polishing pad (polishing layer), 2 a polishing platen, 3 a polishing agent (slurry), 4 an object to be polished (semiconductor wafer), 5 a support (polishing head), 6 and 7 each a rotating shaft.

1. A polishing pad having a polishing layer comprising a polyurethane foam having fine cells, wherein
the polyurethane foam includes a reaction cured body of a polyurethane raw material composition containing:
(1) an isocyanate-terminated prepolymer (A) obtained by reacting a prepolymer raw material composition (A′) containing an isocyanate monomer, a high molecular weight polyol (a) and a low molecular weight polyol,
(2) an isocyanate-terminated prepolymer (B) obtained by reacting a prepolymer raw material composition (B′) containing a polymerized diisocyanate and a high molecular weight polyol (b), and
(3) a chain extender; and
the polymerized diisocyanate contains pentamers or higher oligomers in an amount of 40% by weight or less.

2. The polishing pad according to claim 1, wherein the isocyanate-terminated prepolymer (B) has a viscosity at 50° C. of 8000 mPa·s or less.

3. The polishing pad according to claim 1, wherein the high molecular weight polyol (a) is a polyether polyol having a number average molecular weight of 500 to 5000, and the isocyanate monomer includes toluene diisocyanate and dicyclohexylmethane diisocyanate and/or isophorone diisocyanate.

4. The polishing pad according to claim 1, wherein the high molecular weight polyol (b) is a polyether polyol having a number average molecular weight of 250 to 1000, the polymerized diisocyanate is a polymerized hexamethylene diisocyanate of isocyanurate type and/or biuret type, and the prepolymer raw material composition (B′) has an NCO index of 3.5 to 6.0.

5. The polishing pad according to claim 1, wherein the content of the isocyanate-terminated prepolymer (B) is 5 to 30 parts by weight with respect to 100 parts by weight of the isocyanate-terminated prepolymer (A).

6. The polishing pad according to claim 1, wherein the number of air voids each having a diameter of 500 μm or more in the polyurethane foam is 5 air voids/φ775 mm or less.

7. The polishing pad according to claim 1, wherein the polyurethane foam has an average cell diameter of 20 to 70 μm, a dressing rate of 1.0 μm/minute or less, a dimensional change rate of 0.6% or less when absorbing water, and a bending elastic modulus change rate of 45% or less before and after absorption of water.

8. The polishing pad according to claim 1, wherein the polyurethane foam has an Asker D hardness of 45 to 65 degrees.

9. A method for producing a polishing pad, comprising the steps of mixing a first component containing an isocyanate-terminated prepolymer with a second component containing a chain extender; and curing the mixture to prepare a polyurethane foam, wherein:
the steps include adding a silicone-based surfactant to the first component containing an isocyanate-terminated prepolymer so that the polyurethane foam contains 0.05 to 10% by weight of the silicone-based surfactant; further stirring the first component together with a non-reactive gas to prepare a cell dispersion liquid in which the non-reactive gas is dispersed in the form of fine cells; and then mixing the second component containing a chain extender with the cell dispersion liquid, followed by curing the mixture to prepare the polyurethane foam, and
the isocyanate-terminated prepolymer is
(1) an isocyanate-terminated prepolymer (A) obtained by reacting a prepolymer raw material composition (A′) containing an isocyanate monomer, a high molecular weight polyol (a) and a low molecular weight polyol, and
(2) an isocyanate-terminated prepolymer (B) obtained by reacting a prepolymer raw material composition (B′) containing a polymerized diisocyanate and a high molecular weight polyol (b), and
the polymerized diisocyanate contains a pentamer or a higher oligomer in an amount of 40% by weight or less.

10. The method for producing a polishing pad according to claim 9, wherein the isocyanate-terminated prepolymer (B) has a viscosity at 50° C. of 8000 mPa·s or less.

11. A method for manufacturing a semiconductor device, comprising the step of polishing a surface of a semiconductor wafer using the polishing pad according to claim 1.

12. The polishing pad according to claim 2, wherein the high molecular weight polyol (a) is a polyether polyol having a number average molecular weight of 500 to 5000, and the isocyanate monomer includes toluene diisocyanate and dicyclohexylmethane diisocyanate and/or isophorone diisocyanate.

13. The polishing pad according to claim 2, wherein the high molecular weight polyol (b) is a polyether polyol having a number average molecular weight of 250 to 1000, the polymerized diisocyanate is a polymerized hexamethylene diisocyanate of isocyanurate type and/or biuret type, and the prepolymer raw material composition (B′) has an NCO index of 3.5 to 6.0.

14. The polishing pad according to claim 2, wherein the content of the isocyanate-terminated prepolymer (B) is 5 to 30 parts by weight with respect to 100 parts by weight of the isocyanate-terminated prepolymer (A).

15. The polishing pad according to claim 2, wherein the number of air voids each having a diameter of 500 μm or more in the polyurethane foam is 5 air voids/φ775 mm or less.

16. The polishing pad according to claim 2, wherein the polyurethane foam has an average cell diameter of 20 to 70 μm, a dressing rate of 1.0 μm/minute or less, a dimensional change rate of 0.6% or less when absorbing water, and a bending elastic modulus change rate of 45% or less before and after absorption of water.

17. The polishing pad according to claim 2, wherein the polyurethane foam has an Asker D hardness of 45 to 65 degrees.

18. A method for manufacturing a semiconductor device, comprising the step of polishing a surface of a semiconductor wafer using the polishing pad according to claim 2.

19. A method for manufacturing a semiconductor device, comprising the step of polishing a surface of a semiconductor wafer using the polishing pad according to claim 3.

20. A method for manufacturing a semiconductor device, comprising the step of polishing a surface of a semiconductor wafer using the polishing pad according to claim 4.
